(19) United States
(12) Patent Application Publication
(10) Pub. No.: US 2008/0231991 A1
(43) Pub. Date: Sep. 25, 2008

(54) Method of Manufacturing a Magneto-Optical Device

(75) Inventor: Rudolf Johan Maria Vullers, Eindhoven (NL)

Correspondence Address: PHILIPS INTELLECTUAL PROPERTY & STANDARDS, P.O. BOX 3001, BRIARCLIFF MANOR, NY, 10510, US

(73) Assignee: KONINKLIJKE PHILIPS ELECTRONIC, N.V., EINDHOVEN (NL)

(21) Appl. No.: 10/597,160

(22) PCT Filed: Jan. 7, 2005
(86) PCT No.: PCT/IB2005/050087

§ 371 Date: Jul. 13, 2006

(30) Foreign Application Priority Data
Jan. 19, 2004 (EP) 04100146.2

(51) Int. Cl. G11B 5/127; H01L 21/311; H01L 21/00

(52) U.S. Cl. 360/110; 438/700; 438/3; 257/E21.208

(57) ABSTRACT

Method of manufacturing a magneto-optical device, wherein at least one coil (3) is embedded in an oxide layer (2), wherein the oxide layer (2) is provided with at least one aperture (4). Wherein said aperture (4) is etched selectively in said oxide layer (2) with the use of a sloping side wall (6) of at least one turn (6) of said coil (3).

### BACKGROUND OF THE INVENTION

The invention relates to a method of manufacturing a magneto-optical device.

Such a method is described in the European patent application EP 03101884.9 of the applicant, which is incorporated herein by reference. This prior application was not yet published on the filing date of the present application.

Magneto-optical devices are used for high-density magneto-optical reading of and/or writing on information carriers. Such a device comprises a magnetic field modulation (MFM) coil for focusing a polarized light beam, particularly a laser beam, onto the information carrier. The coil may be embedded in an oxide layer.

A problem of such magneto-optical devices is that water vapor may condense thereon during use. The condensed vapor hinders the transmission of the light beam. In the European patent application EP 03101884.9, it is proposed to provide an oxide layer with an aperture at or around a center of the coil for resolving said problem. The application of such an aperture can prevent condensation of water vapor in the light path of the optical reading and/or writing bean. The aperture can be etched and has steep side walls, for example. It is relatively difficult, however, to form such an aperture relatively fast and economically.

### SUMMARY OF THE INVENTION

It is an object of the invention to provide an improved method of manufacturing a magneto-optical device.

According to the present invention, this object is achieved by the features of claim 1.

According to the invention, at least one coil is embedded in an oxide layer, which oxide layer is provided with at least one aperture, wherein said aperture is etched selectively in said oxide layer with the use of a sloping side wall of at least one turn of said coil.

Since said aperture is etched selectively in said oxide layer, a self-aligned aperture can be obtained, reducing the manufacturing time as well as the manufacturing cost of the magneto-optical device. The selective etching is achieved with the use of a sloping side wall of at least one turn of said coil. Therefore, the aperture can be formed at a desired location with a relatively high accuracy. Besides, in this way, the selectively etched aperture can be given steep side walls. It has been found that the etching speed of oxide can differ owing to a presence of a sloping side wall below the oxide. The present invention uses this aspect to advantage in the manufacture of a magneto-optical device.

It is to be noted that a method of selective etching of an oxide is generally described in the European patent application EP02080573.5 of the applicant, which is incorporated herein by reference. This application was not yet published on the filing date of the present application.

The invention also relates to a magneto-optical device. The magneto-optical device, which is at least partially manufactured by the method according to the invention, may advantageously be used for reading and/or writing information, since a correct reading and/or writing of the information is enhanced by said aperture.

The invention further relates to the use of the magneto-optical device according to the invention.

Further advantageous embodiments of the invention are described in the dependent claims.

The invention will now be described in more detail on the basis of exemplary embodiments shown in the accompanying drawing.

### BRIEF DESCRIPTION OF THE DRAWING

FIG. 1 is a schematic cross-sectional view of the use of an embodiment of the invention;

FIG. 2 shows a first step of the selective etching of an oxide layer;

FIG. 3 shows a second step of the selective etching of an oxide layer;

FIG. 4 shows a first step of a first embodiment according to the present invention;

FIG. 5 shows a second step of the first embodiment;

FIG. 6 shows a third step of the first embodiment;

FIG. 7 shows a fourth step of the first embodiment;

FIG. 8 shows a fifth step of the first embodiment;

FIG. 9 shows a sixth step of the first embodiment;

FIG. 10 shows a seventh step of the first embodiment;

FIG. 11 shows a first step of a second embodiment according to the present invention; and

FIG. 12 shows a second step of the second embodiment.

### DETAILED DESCRIPTION OF THE PREFERRED EMBODIMENTS

FIG. 1 schematically shows the use of a magneto-optical device H. The device H of the present embodiment is a reading and/or writing head, which comprises a lens L and a coil 3 for projecting a light beam B onto an information carrying layer 101 of an information carrier 100. Said light beam B may be for example, a laser-generated polarized beam. Said coil 3 comprises a number of turns 5 of an electrically conductive material, for example a metal, particularly copper or the like. The coil 3 is substantially concentrically aligned with respect to the optical axis OA of the lens L, so that the lens L can direct said light beam B through the center of the coil 3 onto the information carrier 100.

The device H comprises a substrate 1 of transparent material, for example glass. The substrate serves as a coil holder. To this end, an oxide layer 2, in which said coil 3 has been embedded, has been provided on said substrate 1. Said oxide layer 2 may comprise, for example, aluminum oxide (Al₂O₃). During use, the outer surface of the oxide layer 2 is at a relatively short distance FWD from the information carrier 100, for example a distance FWD of about 20 microns or less. The light beam B heats up the information carrier 100, which may lead to evaporation of water therefrom. The resulting water vapor may condense onto the surface of the oxide layer 2, hampering a proper functioning of the device H. In the embodiment of the device H shown in FIG. 1, the oxide layer 2 comprises an aperture 4 which extends through the center of the coil 3, between the outer surface of the oxide layer and the surface 11 of the substrate 1. The aperture 4 prevents condensation of water vapor in the light path of the light beam B.

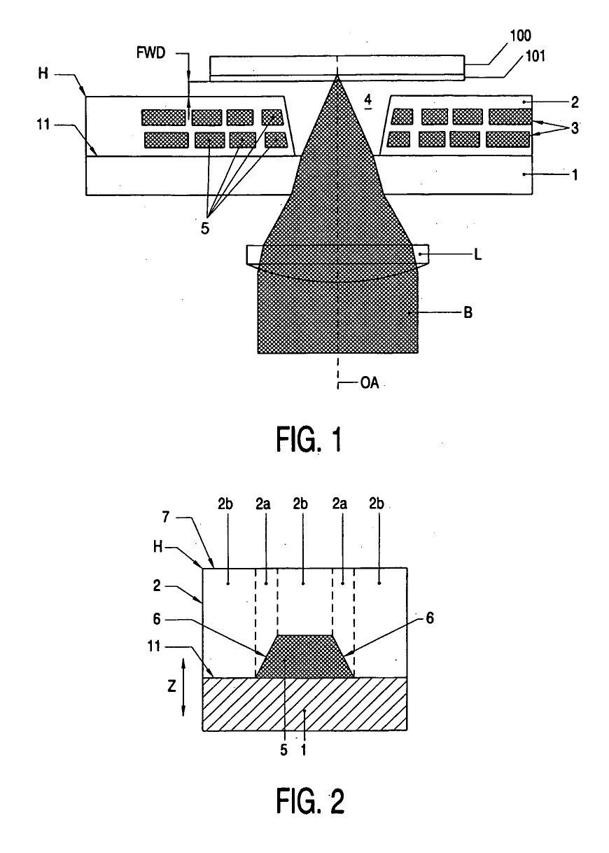

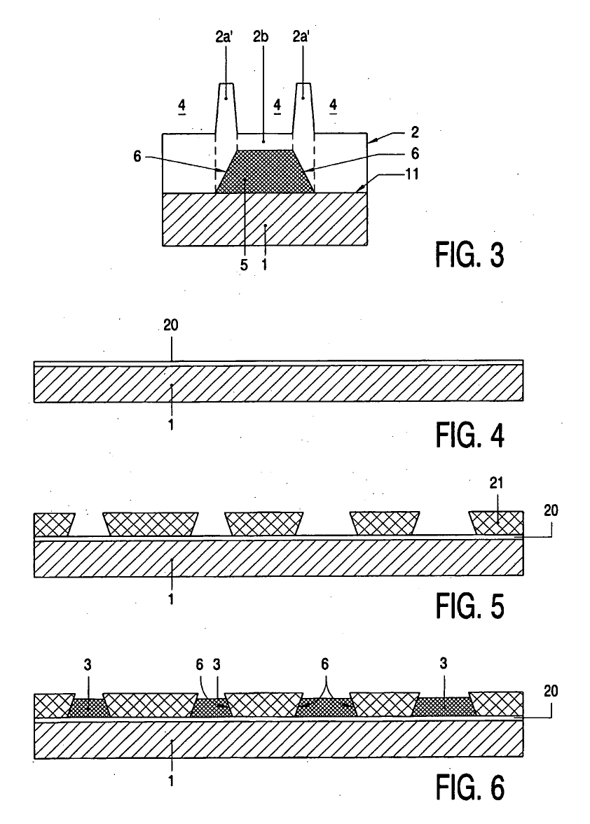

According to the present invention, the oxide layer 2 of the magnetic-optical device H is provided with at least one aperture 4 by selective etching of the aperture 4 in said oxide layer 2 with the use of a sloping side wall 6 of at least one turn 5 of said coil 3. FIGS. 2 and 3 schematically show the principle of the selective etching of the oxide layer 2. It has been found that the etching speed of the oxide layer 2 is relatively low above a sloping side wall 6 of an underlying structure compared with the etching speed of a remaining part of the oxide layer. This depends inter alia on the compounds used. Good results are obtained when the oxide layer 2 is an aluminum oxide (Al₂O₃) layer.

In FIG. 2, a metal coil part 5 comprising sloping side walls 6, has been provided on the surface 11 of a substrate 1. The sloping side walls 6 face away from said substrate surface 11. The metal part 5 is embedded in an oxide layer 2 which has been deposited onto substrate surface 11. The oxide layer 2 comprises first parts 2a which extend substantially between said sloping side walls 6 and a top surface 7 of the oxide layer 2, viewed in a direction Z which is perpendicular to said oxide layer surface 7. The remaining, second parts 2b of the oxide layer 2 extend between and next to said first parts 2a. When a suitable etchant, for example a wet etchant, is applied to the top surface 7 of the oxide layer 2, the first oxide parts 2a are etched much more slowly than the second oxide parts 2b, leading to a structure as shown in FIG. 3. The resulting structure comprises apertures 4 which extend between the remaining parts 2a′ of the first oxide layer parts 2a. Besides wet etching, dry etching techniques may also be used for etching the aperture 4 in the oxide layer. However, the use of a wet etching technique has the advantages of simplicity, a higher processing speed, and lower processing costs over the use of dry etching.

FIGS. 4-10 show a first embodiment of a method of manufacturing a magneto-optical device, using the selective etching of the oxide layer 2. The method at least partially makes use of the manufacturing methods as described in EP 03101884.9 and EP 02080573.5.

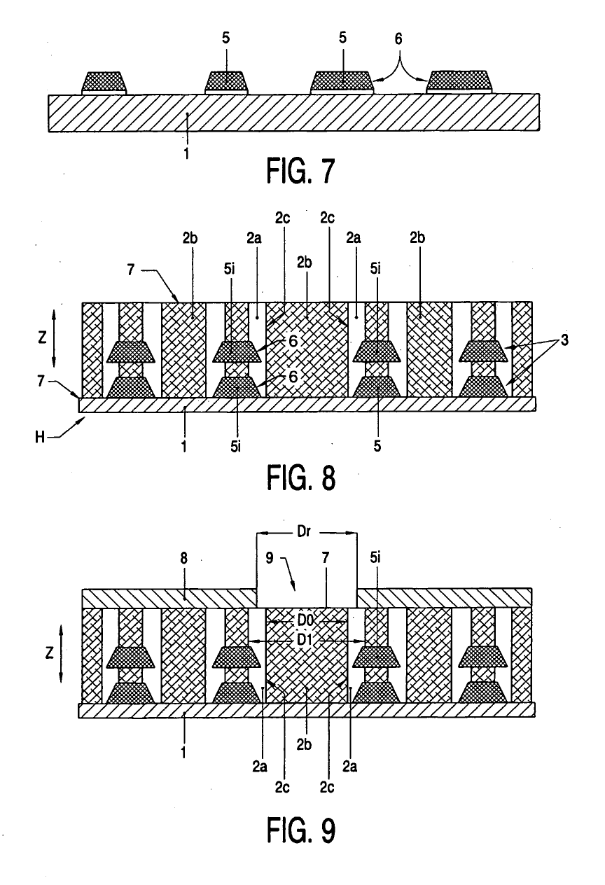

FIG. 4 shows a first step, wherein at least one metal layer 20 is deposited on a substrate 1. Then, a resist layer 21 is deposited. The resist layer 21 is patterned with a negative coil pattern, using standard lithography techniques. The result is shown in FIG. 5. After the patterning of the resist layer 21, a metal 3 is deposited, preferably in an electroplating process, for forming a metal coil pattern comprising said sloping side wall 6, as is shown in FIG. 6. Then, the patterned resist layer 21 is removed. Said metal 3 and metal layer or metal layers 20 are partly removed from the substrate 1 after the resist 21 has been removed, for example by sputter etching, leading to a first coil structure layer as shown in FIG. 7. After that, the oxide layer 2 is deposited on the substrate 1, so that the coil structure 3 is embedded therein. Preferably, the surface 7 of the deposited oxide layer 2 is planarized. The above steps may be repeated so as to form a second coil structure layer, leading to a device structure which is schematically shown in FIG. 8.

In FIG. 8, the device H comprises a coil 3 having inner turns 5i with sloping inner side walls 6. A first part 2a of said oxide layer 2 extends at least above the sloping inner side walls 6 of the inner coil windings 5i and below a surface 7 of the oxide layer 2, viewed in the axial coil direction Z. Said first oxide layer part 2a also extends partly along the edges of the sloping inner side walls 6, viewed in the axial coil direction Z, see FIG. 8. As is shown in FIG. 8, a second oxide layer part 2b adjoins said first oxide layer part 2a. This second oxide layer 2b part is surrounded by said first oxide layer part 2a, viewed in a radial direction which is perpendicular to said axial direction Z.

As in FIGS. 2 and 3, a central aperture 4 is etched selectively in the device structure shown in FIG. 8, preferably by a wet etching technique. The aperture 4 to be formed extends through the area which is enclosed by the inner turns 5i of the coil 3. To this end, the slopes of the inner side walls 6 of the inner turns 5i of said coil 3 are used for selectively etching said aperture 4. More particularly, the surrounding first part 2a of said oxide layer 2 is used to restrict the etching to the central second oxide layer part 2b.

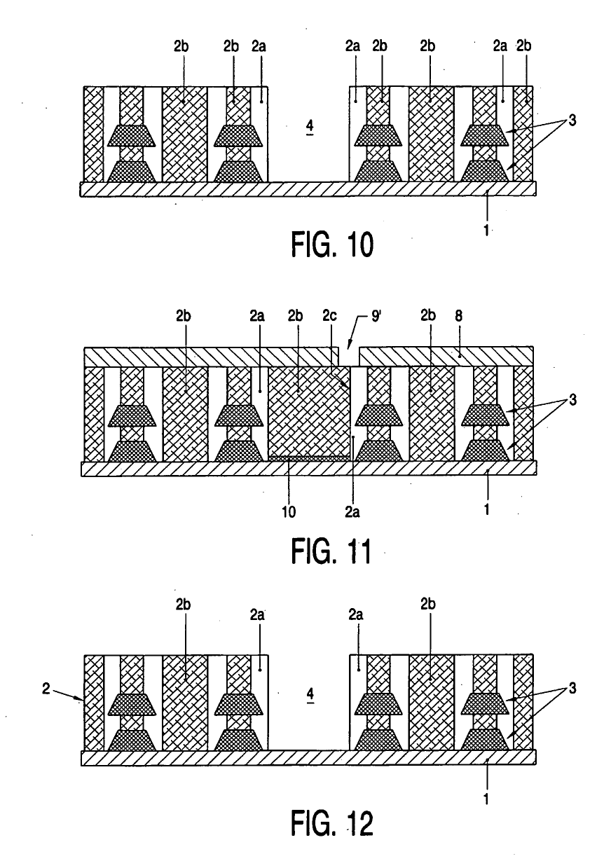

As is shown in FIGS. 9 and 10, such an aperture 4 can be obtained by applying a resist layer 8 onto said oxide surface 7. An aperture 9 is provided in said resist layer 8, by means of lithography techniques. The resist aperture 9 provides access to the surface of said second oxide layer part 2b. In the present embodiment, said resist aperture 9 extends over the edge 2c between said first and second oxide layer parts 2a, 2b. The diameter Dᵣ of the resist aperture 9 is larger than the smallest diameter D₀ of the inner side wall 6 of said inner coil turn 5i. Besides, the diameter Dᵣ of the resist aperture 9 is smaller than the largest diameter D₁ of the inner side wall of said inner coil turn 5i. The resulting resist aperture 9 is depicted in FIG. 9.

As is shown in FIG. 10, an etchant is applied to the exposed surface 7 of the oxide layer 2 such that the second oxide part 2b, which extends through the center of the coil 3, is removed from the oxide layer 2. The etching is selective, since said central oxide part 2b is surrounded by the first oxide part 2a which is etched relatively slowly, see for example FIG. 3. Consequently, the slope of the inner side wall 6 of the inner turns 5i of said coil 3 is used for selectively etching said aperture 4. The etching can be stopped at a desired moment to provide an aperture 4 with a certain desired depth. In the present embodiment, the aperture 4 extends all the way from the oxide layer surface 7 down to the substrate surface 11.

Since the first oxide part 2a restricts the etching substantially to the central second oxide part 2b, an aperture 4 with a relative steep inner wall can be obtained. If a wet etching method is applied, the etching can be performed relatively fast and economically. Besides, the diameter Dᵣ of the resist aperture 9 can be chosen or vary in a relatively broad range, allowing for relatively high tolerances concerning the patterning of a resist aperture 9 in the resist layer 8.

FIGS. 11 and 12 show a second embodiment, which differs from the embodiment shown in FIGS. 4-10 in that the resist aperture 9′ extends only over a portion of the second oxide layer part 2b. An etch stop 10 is provided below said oxide layer 2, so that the etching process substantially ends when an aperture 4 with a desired depth has been etched in the oxide layer 2. In the second embodiment, the second oxide part 2b can be removed by supplying a wet etchant to the resist aperture 9′, resulting in a central aperture 4 having steep side walls. Similar to the first embodiment, the first oxide parts 2a prevent a further etching in a radial direction, which radial direction is perpendicular to said axial direction Z. Therefore, the aperture 4 is etched selectively. The etch stop 10 may prevent etching of the underlying substrate 1. Besides, the etch stop 10 may be used as a signaling element which becomes visible when the central oxide part 2b has been removed, so that the etching process can be stopped in time.

In the second embodiment, the size and location of the resist aperture 9′ can be varied over broad ranges. Therefore, the resist aperture 9′ can be made by means of low-precision tools, for example low-precision lithography tools, puncturing tools, a needle, or suchlike. This results in relatively inexpensive end products, for example reading and/or writing heads and apparatus comprising such heads.

Although the illustrative embodiments of the present invention have been described in greater detail with reference to the accompanying drawing, it is to be understood that the invention is not limited to those embodiments. Various changes or modifications may be effected by those skilled in the art without departing from the scope or the spirit of the invention as defined in the claims.

The magneto-optical device can be made in different forms and may comprise different materials.

Each coil may be, for example, incorporated on a slider, an actuator, or the like.

Each oxide layer may comprise, for example, a metal oxide, a semiconductor oxide, or the like.

Each coil may comprise one or more layers of coil turns 5.

Each turn 5 of the coil may have different shapes, for example circular, square, and/or any other suitable shape. Besides, each turn may be provided with different cross-sections, for example trapezoidal, triangular, semi-circular cross-sections or the like.

Furthermore, one or more parts of a magneto-optical device H may be manufactured on one substrate 1.

Besides, the self-aligned aperture 4 may extend in various parts of the oxide layer, for example above an embedded coil 3, through an embedded coil 3, and/or the like. The selectively etched aperture 4 may have a depth which is smaller than the thickness of the oxide layer 2. The self-aligned aperture 4 may also reach up to or extend through parts of said substrate 1.

1. Method of manufacturing a magneto-optical device, comprising the steps of embedding at least one coil (3) in an oxide layer (2), providing the oxide layer (2) with at least one aperture (4), selectively etching said aperture (4) in said oxide layer (2) with the use of a sloping side wall (6) of at least one turn (5) of said coil (3).

2. Method according to claim 1, wherein the slope of an inner side wall (6) of an inner turn (5i) of said coil (3) is used for selectively etching said aperture (4), such that said aperture (4) extends above and/or through a center of said coil (3).

3. Method according to claim 1, wherein a first part (2a) of said oxide layer (2) at least extends between said sloping side wall (6) of said coil turn (5) and a surface (7) of the oxide layer (2), viewed in an axial coil direction (Z), and wherein said aperture (4) is formed by etching of at least a portion of a second part (2b) of said oxide layer (2), which second oxide layer part (2a) adjoins said first oxide layer part (2a).

4. Method according to of claim 3, wherein a resist layer (8) is provided on said oxide layer surface (7), wherein said resist layer (8) is provided with an aperture (9) which at least provides access to part of the surface of said second oxide layer part (2b), and wherein said second oxide layer part (2b) is etched by means of an etchant that is provided to said resist aperture (9).

5. Method according to claim 2, wherein a diameter (Dᵣ) of the resist aperture (9) is chosen to be larger than the smallest diameter (D₀) of the inner side wall of said inner coil turn (5i), and wherein the diameter (Dᵣ) of the resist aperture (9) is chosen smaller than the largest diameter (D₁) of the inner side wall of said inner coil winding (5i).

6. Method according to claim 1, wherein an etch stop (10) is provided in and/or below said oxide layer (2), such that the etching of said aperture (4) substantially ends when the aperture (4) has reached a desired depth.

7. Method according to claim 1, wherein said at least one coil (3) is embedded in said oxide layer (2) by at least the following steps:
depositing a resist layer (21) on a substrate (1);
patterning the resist layer (21) with a negative coil pattern;
depositing metal (3), preferably in an electroplating process, for forming a metal coil pattern comprising said sloping side wall (6);
removing said patterned resist layer (21); and
depositing the oxide layer (2), whereupon the surface (7) of the oxide layer (2) is preferably planarized.

8. Method according to claim 7, wherein at least one metal layer (20) is deposited on the substrate (1) before said resist layer (20) is deposited on the substrate (1), and wherein said metal (3) and metal layer (20) are partly removed from the substrate (1) after the resist (21) has been removed, for example by sputter etching.

9. Method according to claim 1, wherein said oxide layer (2) at least comprises aluminum oxide.

10. Method according to claim 1, wherein a wet etching technique is used for etching the aperture (4) in said oxide layer (2).

11. Magneto-optical device, at least partially manufactured by the method according to claim 1.

12. Use of the magneto-optical device according to claim 11 for reading and/or writing information.
